(19) United States
(12) Patent Application Publication
(10) Pub. No.: US 2025/0107142 A1
(43) Pub. Date: Mar. 27, 2025

(54) SEMICONDUCTOR DEVICE

(71) Applicants: Kabushiki Kaisha Toshiba, Tokyo (JP); Toshiba Electronic Devices & Storage Corporation, Tokyo (JP)

(72) Inventors: Takuya YASUTAKE, Kanazawa Ishikawa (JP); Hiroaki KATOU, Nonoichi Ishikawa (JP); Tatsuya NISHIWAKI, Yokohama Kanagawa (JP); Kenya KOBAYASHI, Nonoichi Ishikawa (JP); Tsuyoshi KACHI, Kanazawa Ishikawa (JP)

(21) Appl. No.: 18/437,906

(22) Filed: Feb. 9, 2024

(30) Foreign Application Priority Data
Sep. 21, 2023 (JP) 2023-156429

(51) Int. Cl. H01L 29/78; H01L 29/06; H01L 29/40; H01L 29/423; H01L 29/66

(52) U.S. Cl. CPC H10D 30/668; H10D 30/0297; H10D 62/109; H10D 64/117; H10D 64/516

(57) ABSTRACT

A semiconductor device includes first to fourth electrodes, first to third semiconductor regions, and first and second insulating parts. The third electrode includes first to third electrode regions. The third electrode region connects the first electrode region and the second electrode region. The first insulating part includes first to third insulating regions. The first insulating region includes first and second insulating portions. The second insulating region includes third and fourth insulating portions. The third insulating region connects the first insulating region and the second insulating region. The third insulating region includes fifth and sixth insulating portions. A lower end of the sixth insulating portion is positioned lower than a lower end of the second insulating portion and a lower end of the fourth insulating portion.

### CROSS-REFERENCE TO RELATED APPLICATIONS

This application is based upon and claims the benefit of priority from Japanese Patent Application No. 2023-156429, filed on Sep. 21, 2023; the entire contents of which are incorporated herein by reference.

### FIELD

Embodiments described herein relate generally to a semiconductor device.

### BACKGROUND

A semiconductor device such as a MOSFET (Metal Oxide Semiconductor Field Effect Transistor) or the like is used in power conversion and the like. It is desirable to relax the electric field of the semiconductor device.

### BRIEF DESCRIPTION OF THE DRAWINGS

FIG. 1 is a plan view illustrating a semiconductor device according to a first embodiment;

FIG. 2 is a plan view illustrating a portion of the semiconductor device according to the first embodiment;

FIG. 3 is a cross-sectional view illustrating a portion of the semiconductor device according to the first embodiment;

FIG. 4 is a cross-sectional view illustrating a portion of the semiconductor device according to the first embodiment;

FIG. 5 is a cross-sectional view illustrating a portion of the semiconductor device according to the first embodiment;

FIG. 6 is a cross-sectional view illustrating a portion of a semiconductor device according to a first modification of the first embodiment;

FIG. 7 is a cross-sectional view illustrating a portion of a semiconductor device according to a second modification of the first embodiment;

FIG. 8 is a cross-sectional view illustrating a portion of a semiconductor device according to a third modification of the first embodiment;

FIG. 9 is a plan view illustrating a portion of a semiconductor device according to a second embodiment;

FIG. 10 is a cross-sectional view illustrating a portion of the semiconductor device according to the second embodiment;

FIGS. 11A to 11E are cross-sectional views illustrating an example of a manufacturing method of the semiconductor device according to the first embodiment;

FIGS. 12A to 12E are cross-sectional views illustrating an example of a manufacturing method of a semiconductor device according to a second modification of the first embodiment; and

FIGS. 13A to 13H are cross-sectional views illustrating an example of a manufacturing method of the semiconductor device according to the second embodiment.

### DETAILED DESCRIPTION

A semiconductor device according to an embodiment includes a first electrode, a first semiconductor region of a first conductivity type, a second semiconductor region of a second conductivity type, a third semiconductor region of the first conductivity type, a second electrode, a third electrode, a first insulating part, a fourth electrode, and a second insulating part. The first semiconductor region is located on the first electrode. The second semiconductor region is located on the first semiconductor region. The third semiconductor region is located on the second semiconductor region. The second electrode is located on the third semiconductor region. The second electrode is electrically connected with the third semiconductor region. The third electrode includes a first electrode region, a second electrode region, and a third electrode region. The first electrode region extends along a second direction. The second direction is perpendicular to a first direction; and the first direction is from the first electrode toward the second electrode. The first electrode region is arranged with the second semiconductor region in a third direction. The third direction is perpendicular to the first direction and crosses the second direction. The second electrode region extends along the third direction. The second electrode region is arranged with the second semiconductor region in the second direction. The third electrode region connects the first electrode region and the second electrode region. The first insulating part includes a first insulating region, a second insulating region, and a third insulating region. The first insulating region includes a first insulating portion and a second insulating portion. The first insulating portion is located between the second semiconductor region and the first electrode region in the third direction. The second insulating portion is located between the first semiconductor region and the first electrode region in the first direction. The second insulating region includes a third insulating portion and a fourth insulating portion. The third insulating portion is located between the second semiconductor region and the second electrode region in the second direction. The fourth insulating portion is located between the first semiconductor region and the second electrode region in the first direction. The third insulating region connects the first insulating region and the second insulating region. The third insulating region includes a fifth insulating portion and a sixth insulating portion. The fifth insulating portion is located between the second semiconductor region and the third electrode region in a fourth direction. The fourth direction is perpendicular to the first direction and crosses the second and third directions. The sixth insulating portion is located between the first semiconductor region and the third electrode region in the first direction. The fourth electrode is arranged with the first semiconductor region and the third electrode in the second and third directions. The second insulating part is located between the fourth electrode and the first semiconductor region and between the fourth electrode and the third electrode in the second and third directions. A lower end of the sixth insulating portion is positioned lower than a lower end of the second insulating portion and a lower end of the fourth insulating portion.

Embodiments of the invention will now be described with reference to the drawings.

The drawings are schematic or conceptual; and the relationships between the thickness and width of portions, the proportions of sizes among portions, etc., are not necessarily the same as the actual values. The dimensions and proportions may be illustrated differently among drawings, even when the same portion is illustrated.

In the specification and drawings, components similar to those already described are marked with the same reference numerals; and a detailed description is omitted as appropriate.

In the following description and drawings, the notations of n⁺, n⁻, p⁺, and p indicate relative levels of the impurity concentrations. Namely, a notation marked with “+” indicates that the impurity concentration is relatively greater than that of a notation not marked with either “+” or “−”; and a notation marked with “−” indicates that the impurity concentration is relatively less than that of an unmarked notation. When both a p-type impurity and an n-type impurity are included in each region, these notations indicate relative levels of the net impurity concentrations after the impurities compensate each other.

In the embodiments described below, each embodiment may be implemented by inverting the p-type and the n-type of the semiconductor regions.

### First Embodiment

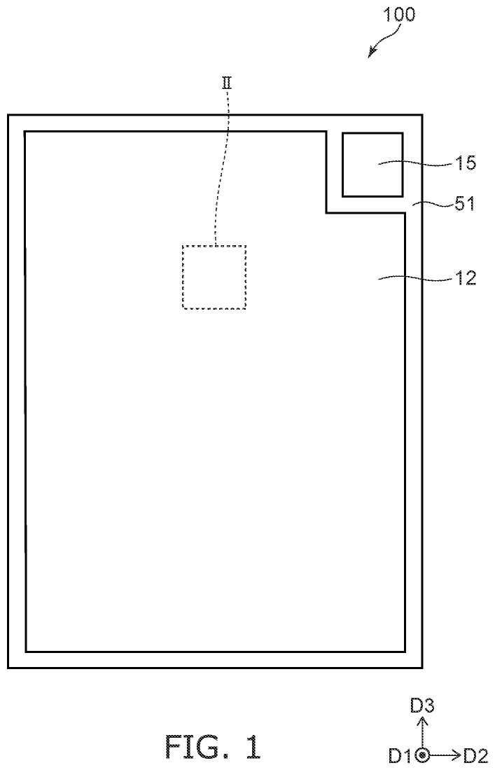

FIG. 1 is a plan view illustrating a semiconductor device according to a first embodiment.

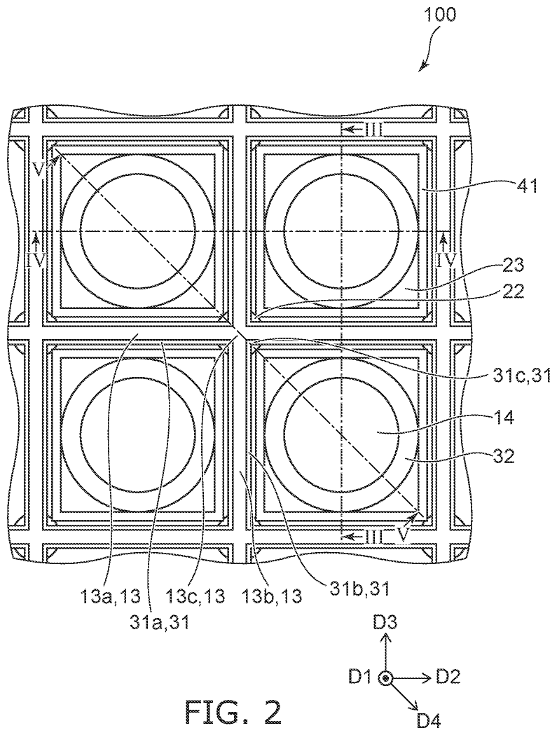

FIG. 2 is a plan view illustrating a portion of the semiconductor device according to the first embodiment.

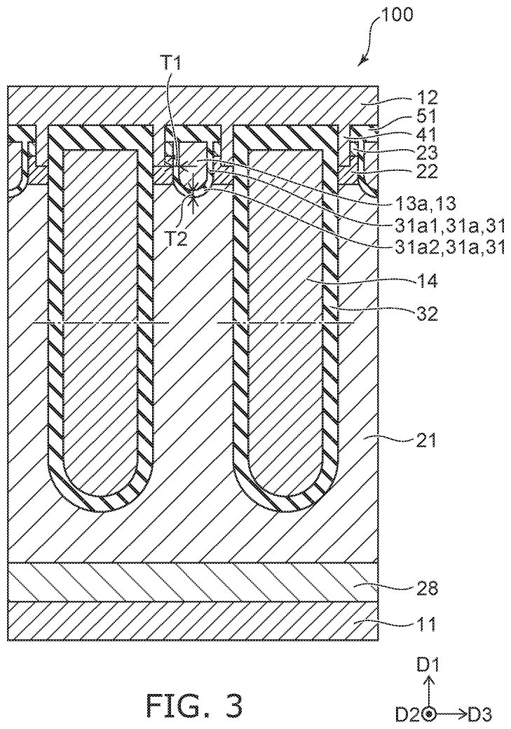

FIGS. 3 to 5 are cross-sectional views illustrating portions of the semiconductor device according to the first embodiment.

FIG. 2 illustrates region II shown in FIG. 1.

FIG. 3 is a cross-sectional view along line III-III shown in FIG. 2.

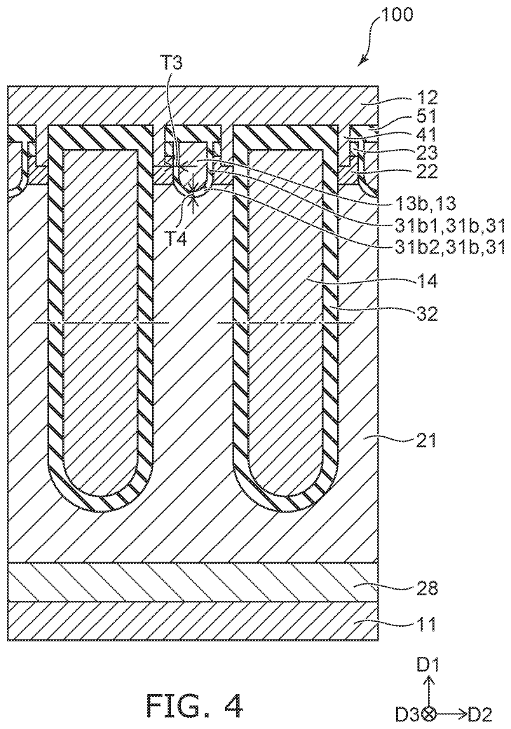

FIG. 4 is a cross-sectional view along line IV-IV shown in FIG. 2.

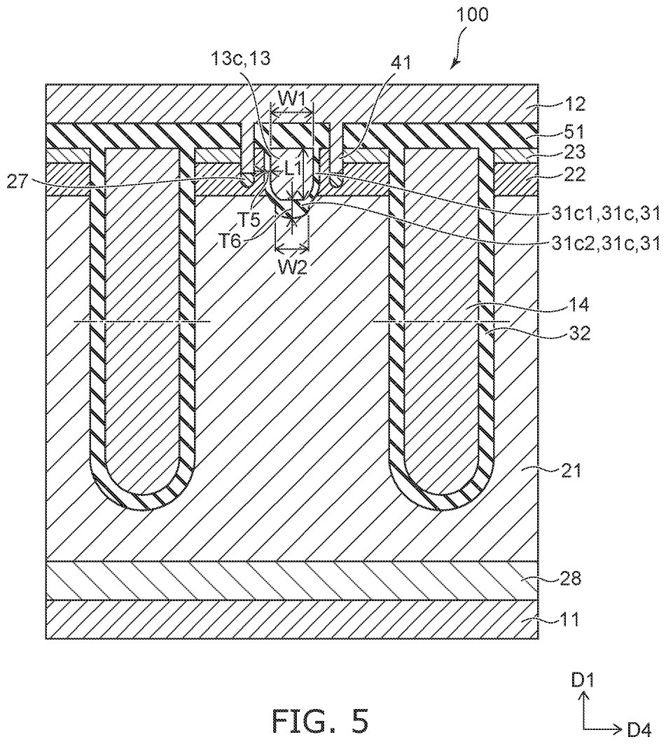

FIG. 5 is a cross-sectional view along line V-V shown in FIG. 2.

The semiconductor device 100 according to the first embodiment is a vertical MOSFET. The semiconductor device 100 is a MOSFET having a so-called dot FP structure.

As illustrated in FIGS. 1 to 5, the semiconductor device 100 includes a drain electrode 11 (a first electrode), a source electrode 12 (a second electrode), a gate electrode 13 (a third electrode), a FP electrode 14 (a fourth electrode), a gate pad 15, an n⁻-type drift region 21 (a first semiconductor region), a p-type base region 22 (a second semiconductor region), an n⁺-type source region 23 (a third semiconductor region), a p⁺-type contact region 27, an n⁺-type drain region 28, a gate insulating part 31 (a first insulating part), a FP insulating part 32 (a second insulating part), a first connection part 41, and an insulating layer 51. In the semiconductor device 100, the first conductivity type is the n-type; and the second conductivity type is the p-type. The source electrode 12 and the insulating layer 51 are not 25 illustrated in FIG. 2.

A first direction D1, a second direction D2, and a third direction D3 are used in the description of the following embodiments. The direction from the drain electrode 11 toward the source electrode 12 is taken as the first direction D1. One direction perpendicular to the first direction D1 is taken as the second direction D2. One direction crossing the first and second directions D1 and D2 is taken as the third direction D3. The third direction D3 may be perpendicular to the second direction D2 or oblique to the second direction D2. A direction that is perpendicular to the first direction D1 and crosses the second and third directions D2 and D3 is taken as a fourth direction D4. Although the direction from the drain electrode 11 toward the source electrode 12 is referred to as “up/above/higher than”, and the opposite direction is referred to as “down/below/lower than” for easier understanding of the description, these directions are independent of the direction of gravity. Being viewed from above is referred to as “viewed in plan”.

As illustrated in FIG. 1, the source electrode 12 and the gate pad 15 are located at the upper surface of the semiconductor device 100. The source electrode 12 and the gate pad 15 are electrically isolated from each other.

As illustrated in FIGS. 3 to 5, the drain electrode 11 is located at the lower surface of the semiconductor device 100. The n⁻-type drift region 21 is located on the drain electrode 11 with the n⁺-type drain region 28 interposed. The n⁻-type drift region 21 is electrically connected with the drain electrode 11 via the n⁺-type drain region 28. The p-type base region 22 is located on the n⁻-type drift region 21. The n⁺-type source region 23 and the p⁺-type contact region 27 are located on the p-type base region 22. The source electrode 12 is located on the p-type base region 22 and the n⁺-type source region 23 with the insulating layer 51 interposed. The source electrode 12 is electrically connected with the p-type base region 22 and the n⁺-type source region 23 via the first connection part 41 and the p⁺-type contact region 27.

The gate electrode 13 is arranged with the p-type base region 22 in the second direction D2, the third direction D3, and the fourth direction D4. As illustrated in FIGS. 2 to 5, the gate electrode 13 includes a first electrode region 13a, a second electrode region 13b, and a third electrode region 13c.

The first electrode region 13a extends along the second direction D2. The first electrode region 13a is arranged with the p-type base region 22 in the third direction D3. In the semiconductor device 100, a portion of the first electrode region 13a is arranged with the n⁻-type drift region 21 in the third direction D3. In the semiconductor device 100, a portion of the first electrode region 13a is arranged with the n⁺-type source region 23 in the third direction D3. In the semiconductor device 100, a portion of the first electrode region 13a is arranged with the first connection part 41 in the third direction D3.

The second electrode region 13b extends along the third direction D3. The second electrode region 13b is arranged with the p-type base region 22 in the second direction D2. In the semiconductor device 100, a portion of the second electrode region 13b is arranged with the n⁻-type drift region 21 in the second direction D2. In the semiconductor device 100, a portion of the second electrode region 13b is arranged with the n⁺-type source region 23 in the second direction D2. In the semiconductor device 100, a portion of the second electrode region 13b is arranged with the first connection part 41 in the second direction D2.

The third electrode region 13c connects the first electrode region 13a and the second electrode region 13b. The third electrode region 13c is positioned at the crossing point between the first electrode region 13a and the second electrode region 13b. In the semiconductor device 100, the third electrode region 13c is arranged with the p-type base region 22 in the fourth direction D4. In the semiconductor device 100, a portion of the third electrode region 13c is arranged with the n⁻-type drift region 21 in the fourth direction D4. In the semiconductor device 100, a portion of the third electrode region 13c is arranged with the n⁺-type source region 23 in the fourth direction D4. In the semiconductor device 100, a portion of the third electrode region 13c is arranged with the p⁺-type contact region 27 and the first connection part 41 in the fourth direction D4.

In the semiconductor device 100, the upper end of the first electrode region 13a, the upper end of the second electrode region 13b, and the upper end of the third electrode region 13c are positioned at the same level. The upper end of the first electrode region 13a, the upper end of the second electrode region 13b, and the upper end of the third electrode region 13c may be positioned at mutually-different levels.

In the semiconductor device 100, the lower end of the first electrode region 13a, the lower end of the second electrode region 13b, and the lower end of the third electrode region 13c are positioned at the same level. The lower end of the first electrode region 13a, the lower end of the second electrode region 13b, and the lower end of the third electrode region 13c may be positioned at mutually-different levels.

In the semiconductor device 100, the lower end of the first electrode region 13a, the lower end of the second electrode region 13b, and the lower end of the third electrode region 13c each are positioned higher than the lower end of the FP electrode 14. In the semiconductor device 100, the lower end of the first electrode region 13a, the lower end of the second electrode region 13b, and the lower end of the third electrode region 13c each are positioned higher than the center between the upper end of the FP electrode 14 and the lower end of the FP electrode 14. In FIGS. 3 to 5, the position of the center between the upper end of the FP electrode 14 and the lower end of the FP electrode 14 is illustrated by a single dot-dash line.

The gate insulating part 31 is located between the gate electrode 13 and the p-type base region 22 in the second direction D2, the third direction D3, and the fourth direction D4. As illustrated in FIGS. 2 to 5, the gate insulating part 31 includes a first insulating region 31a, a second insulating region 31b, and a third insulating region 31c.

The first insulating region 31a includes a first insulating portion 31a1 and a second insulating portion 31a2. The first insulating portion 31a1 is located between the p-type base region 22 and the first electrode region 13a in the third direction D3. The second insulating portion 31a2 is located between the n⁻-type drift region 21 and the first electrode region 13a in the first direction D1. The second insulating portion 31a2 is positioned under the first electrode region 13a.

The second insulating region 31b includes a third insulating portion 31b1 and a fourth insulating portion 31b2. The third insulating portion 31b1 is located between the p-type base region 22 and the second electrode region 13b in the second direction D2. The fourth insulating portion 31b2 is located between the n⁻-type drift region 21 and the second electrode region 13b in the first direction D1. The fourth insulating portion 31b2 is positioned under the second electrode region 13b.

The third insulating region 31c connects the first insulating region 31a and the second insulating region 31b. The third insulating region 31c is positioned at the crossing point between the first insulating region 31a and the second insulating region 31b. The third insulating region 31c includes a fifth insulating portion 31c1 and a sixth insulating portion 31c2. The fifth insulating portion 31c1 is located between the p-type base region 22 and the third electrode region 13c in the fourth direction D4. The sixth insulating portion 31c2 is located between the n⁻-type drift region 21 and the third electrode region 13c in the first direction D1. The sixth insulating portion 31c2 is positioned under the third electrode region 13c.

In the semiconductor device 100, the lower end of the sixth insulating portion 31c2 (the third insulating region 31c) is positioned lower than the lower end of the second insulating portion 31a2 (the first insulating region 31a). The lower end of the sixth insulating portion 31c2 (the third insulating region 31c) is positioned lower than the lower end of the fourth insulating portion 31b2 (the second insulating region 31b). The lower end of the second insulating portion 31a2 (the first insulating region 31a) is positioned at the same level as the lower end of the fourth insulating portion 31b2 (the second insulating region 31b).

In the semiconductor device 100, the lower end of the second insulating portion 31a2 (the first insulating region 31a), the lower end of the fourth insulating portion 31b2 (the second insulating region 31b), and the lower end of the sixth insulating portion 31c2 (the third insulating region 31c) each are positioned higher than the lower end of the FP electrode 14. In the semiconductor device 100, the lower end of the second insulating portion 31a2 (the first insulating region 31a), the lower end of the fourth insulating portion 31b2 (the second insulating region 31b), and the lower end of the sixth insulating portion 31c2 (the third insulating region 31c) each are positioned higher than the center between the upper end of the FP electrode 14 and the lower end of the FP electrode 14.

In the semiconductor device 100, a thickness T1 in the third direction D3 of the first insulating portion 31a1, a thickness T3 in the second direction D2 of the third insulating portion 31b1, and a thickness T5 in the fourth direction D4 of the fifth insulating portion 31c1 are equal. The thickness T1, the thickness T3, and the thickness T5 may be different from each other.

In the semiconductor device 100, a thickness T6 in the first direction D1 of the sixth insulating portion 31c2 is greater than a thickness T2 in the first direction D1 of the second insulating portion 31a2. The thickness T6 is greater than a thickness T4 in the first direction D1 of the fourth insulating portion 31b2. The thickness T2 is equal to the thickness T4. The thickness T2 may be different from the thickness T4.

In the semiconductor device 100, the thickness T6 is greater than the thickness T5. In the semiconductor device 100, the thickness T2 is equal to the thickness T1. The thickness T2 may be different from the thickness T1. In the semiconductor device 100, the thickness T4 is equal to the thickness T3. The thickness T4 may be different from the thickness T3.

In the semiconductor device 100, the thickness T6 is greater than half of a length L1 in the first direction D1 of the third electrode region 13c. In the semiconductor device 100, the thickness T6 is less than the length L1.

In the semiconductor device 100, a width W2 in the fourth direction D4 of the sixth insulating portion 31c2 is less than a width W1 in the fourth direction D4 of the third electrode region 13c. In the semiconductor device 100, the width W2 is greater than half of the width W1.

The gate electrode 13 is electrically connected with the gate pad 15. The gate pad 15 is electrically isolated from the source electrode 12. The gate electrode 13 may be electrically connected with the gate pad 15 via a not-illustrated gate wiring layer.

The FP electrode 14 is arranged with the n⁻-type drift region 21 and the gate electrode 13 in the second direction D2, the third direction D3, and the fourth direction D4. In the semiconductor device 100, a portion of the FP electrode 14 is arranged with the p-type base region 22 in the second direction D2, the third direction D3, and the fourth direction D4. A portion of the FP electrode 14 is arranged with the n+-type source region 23 in the second direction D2, the third direction D3, and the fourth direction D4.

The FP insulating part 32 is located between the FP electrode 14 and the n⁻-type drift region 21 and between the FP electrode 14 and the gate electrode 13 in the second direction D2, the third direction D3, and the fourth direction D4. In the semiconductor device 100, a portion of the FP insulating part 32 is located between the FP electrode 14 and the p-type base region 22 in the second direction D2, the third direction D3, and the fourth direction D4. A portion of the FP insulating part 32 is located between the FP electrode 14 and the n⁺-type source region 23 in the second direction D2, the third direction D3, and the fourth direction D4. A portion of the FP insulating part 32 is located between the FP electrode 14 and the n⁻-type drift region 21 in the first direction D1. The FP electrode 14 is electrically connected with the source electrode 12.

The first connection part 41 is located between the FP insulating part 32 and the third insulating region 31c of the gate insulating part 31 in the second direction D2, the third direction D3, and the fourth direction D4. The p⁺-type contact region 27 is located between the first connection part 41 and the p-type base region 22 in the first direction D1. The first connection part 41 electrically connects the source electrode 12 and the p-type base region 22 (the p⁺-type contact region 27).

In the semiconductor device 100 as illustrated in FIG. 2, multiple FP electrodes 14 and multiple FP insulating parts 32 are arranged when viewed in plan. The FP electrodes 14 are arranged in a quadrilateral configuration when viewed in plan. For example, the FP electrodes 14 may be arranged in a triangular configuration when viewed in plan. The gate electrode 13 is located between the multiple FP electrodes 14.

In the semiconductor device 100 as illustrated in FIG. 2, the FP electrode 14 and the FP insulating part 32 are circular when viewed in plan. The FP electrode 14 and the FP insulating part 32 may be, for example, polygonal such as triangular, quadrilateral, hexagonal, etc., when viewed in plan.

An operation of the semiconductor device 100 will now be described.

A voltage that is not less than a threshold is applied to the gate electrode 13 in a state in which a positive voltage with respect to the source electrode 12 is applied to the drain electrode 11. As a result, a channel (an inversion layer) is formed in the p-type base region 22; and the semiconductor device 100 is set to an on-state. Electrons flow from the source electrode 12 toward the drain electrode 11 via the channel. Subsequently, when a voltage that is less than the threshold is applied to the gate electrode 13, the channel in the p-type base region 22 disappears, and the semiconductor device 100 is set to an off-state.

When the semiconductor device 100 is switched to the off-state, the positive voltage with respect to the source electrode 12 that is applied to the drain electrode 11 increases. In other words, the potential difference between the n⁻-type drift region 21 and the FP electrode 14 increases. Due to the increase of the potential difference, a depletion layer spreads toward the n⁻-type drift region 21 from the interface between the FP insulating part 32 and the n⁻-type drift region 21. The spreading of the depletion layer can increase the breakdown voltage of the semiconductor device 100. Or, the on-resistance of the semiconductor device 100 can be reduced by increasing the concentration of the impurity that forms donors in the n⁻-type drift region 21 while maintaining the breakdown voltage of the semiconductor device 100.

Examples of the materials of the components of the semiconductor device 100 will now be described.

The drain electrode 11, the source electrode 12, and the gate pad 15 include metals such as aluminum, copper, etc.

The n⁻-type drift region 21, the p-type base region 22, and the n⁺-type source region 23, a p⁺-type semiconductor region 24 (described below), the p+-type contact region 27, and the n⁺-type drain region 28 include silicon, silicon carbide, gallium nitride, or gallium arsenide as a semiconductor material. When silicon is used as the semiconductor material, arsenic, phosphorus, or antimony can be used as an impurity that forms donors. Boron can be used as an impurity that forms acceptors.

The gate electrode 13 and the FP electrode 14 include conductive materials such as polysilicon, etc. Impurities may be added to the conductive materials.

The gate insulating part 31, the FP insulating part 32, and the insulating layer 51 include insulating materials. The gate insulating part 31, the FP insulating part 32, and the insulating layer 51 include, for example, silicon oxide or silicon nitride.

The first connection part 41 and a second connection part 42 (described below) include metals such as tungsten, aluminum, copper, etc.

Effects of the first embodiment will now be described.

In the semiconductor device 100, multiple FP electrodes 14 are arranged in the second and third directions D2 and D3. According to this structure, compared to when the FP electrodes 14 extend to be continuous in one direction, the volume of the n⁻-type drift region 21 used as the current path can be increased. The on-resistance of the semiconductor device 100 can be reduced thereby. In the semiconductor device 100, the gate electrode 13 includes the first electrode region 13a extending in the third direction D3, and the second electrode region 13b extending in the second direction D2. According to this structure, compared to when the gate electrodes 13 extend to be continuous in one direction, channels are formed in more regions. The channel density is increased, and the on-resistance of the semiconductor device 100 is further reduced. For example, when the on-resistance of the semiconductor device 100 is reduced, the current density that flows through the semiconductor device 100 can be increased. By increasing the current density, the semiconductor device 100 can be smaller. Or, the number of the semiconductor devices 100 necessary to allow a prescribed current to flow can be reduced.

In the semiconductor device 100 as illustrated in FIG. 5, the lower end of the third insulating region 31c positioned under the third electrode region 13c (the lower end of the sixth insulating portion 31c2) is positioned lower than the lower end of the first insulating region 31a positioned under the first electrode region 13a (the lower end of the second insulating portion 31a2) and the lower end of the second insulating region 31b positioned under the second electrode region 13b (the lower end of the fourth insulating portion 31b2). The electric field under the third electrode region 13c can be relaxed thereby.

By setting the thickness T6 to be greater than the thicknesses T2 and T4, the electric field under the third electrode region 13c can be relaxed. Also, the capacitance between the gate electrode 13 and the drain electrode 11 can be reduced.

By setting the thickness T6 to be greater than the thickness T5, the capacitance (Cgd) between the gate electrode 13 and the drain electrode 11 can be reduced and the FOM (Figure of Merit) can be improved without making the fifth insulating portion 31c1 thick. A reduction of the breakdown voltage can be suppressed by filling, with an oxide film or the like, the region where the distance between the FP electrodes 14 is wide and the FP electrodes 14 tend to be less effective.

By setting the thickness T6 to be greater than half of the length L1, electric field relaxation by the sixth insulating portion 31c2 is possible without increasing the gate capacitance (Qg). Effects are obtained in which the capacitance (Cgd) between the gate electrode 13 and the drain electrode 11 is reduced, the reduction of the breakdown voltage is suppressed, etc., without reducing the cross-sectional area of the gate electrode 13 more than necessary (that is, while preventing the gate resistance from becoming too large).

### First Modification

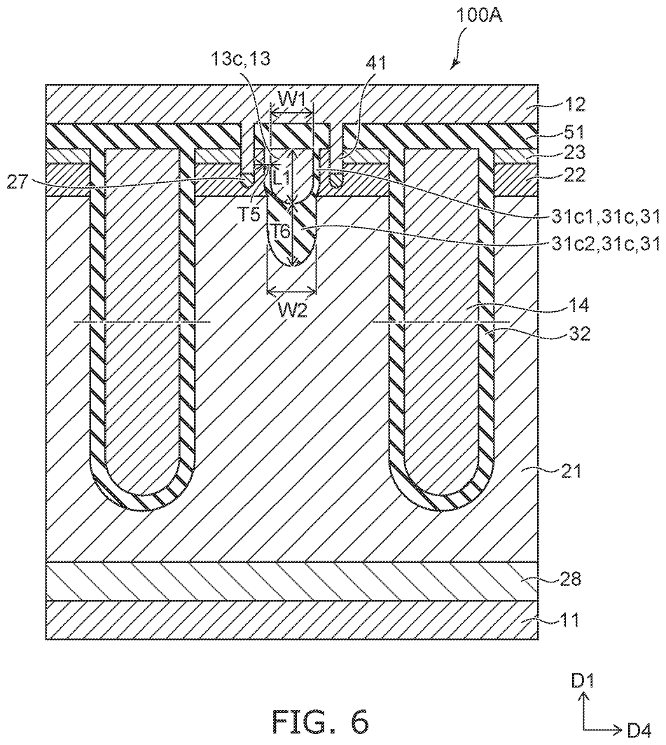

FIG. 6 is a cross-sectional view illustrating a portion of a semiconductor device according to a first modification of the first embodiment.

FIG. 6 illustrates a cross section at a position corresponding to line V-V shown in FIG. 2.

As illustrated in FIG. 6, the shape of the sixth insulating portion 31c2 of the semiconductor device 100A according to the first modification of the first embodiment is different from that of the semiconductor device 100. Otherwise, the semiconductor device 100A is the same as the semiconductor device 100.

In the semiconductor device 100A, the thickness T6 is greater than the length L1. In the semiconductor device 100A, the width W2 is equal to the width W1.

By setting the thickness T6 to be greater than the length L1, the electric field can be relaxed in a wider range. By setting the width W2 to be equal to the width W1, the sixth insulating portion 31c2 positioned under the gate electrode 13 can be prevented from having an incongruous shape, and electric field concentration at the sixth insulating portion 31c2 can be relaxed.

In the semiconductor device 100A, the lower end of the sixth insulating portion 31c2 is positioned higher than the lower end of the FP electrode 14. The lower end of the sixth insulating portion 31c2 may be positioned at the same level as the lower end of the FP electrode 14, or may be positioned lower than the lower end of the FP electrode 14. As a result, the electric field can be relaxed in an even wider range. For example, even when the lower end of the sixth insulating portion 31c2 is positioned lower than the lower end of the FP electrode 14, punch-through to the substrate does not occur because the depletion layer itself does not extend.

### Second Modification

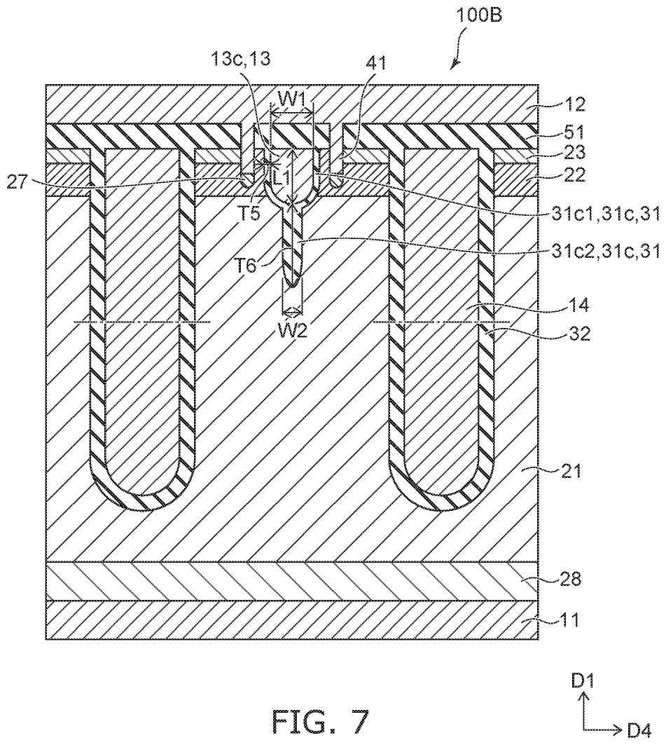

FIG. 7 is a cross-sectional view illustrating a portion of a semiconductor device according to a second modification of the first embodiment.

FIG. 7 illustrates a cross section at a position corresponding to line V-V shown in FIG. 2.

As illustrated in FIG. 7, the shape of the sixth insulating portion 31c2 of the semiconductor device 100B according to the second modification of the first embodiment is different from that of the semiconductor device 100. Otherwise, the semiconductor device 100B is the same as the semiconductor device 100.

In the semiconductor device 100B, the thickness T6 is greater than the length L1. In the semiconductor device 100B, the width W2 is less than half of the width W1.

By setting the thickness T6 to be greater than the length L1, the electric field can be relaxed in a wider range. By setting the width W2 to be less than half of the width W1, the effective area can be reduced while performing electric field relaxation. An increase of the on-resistance can be suppressed thereby.

### Third Modification

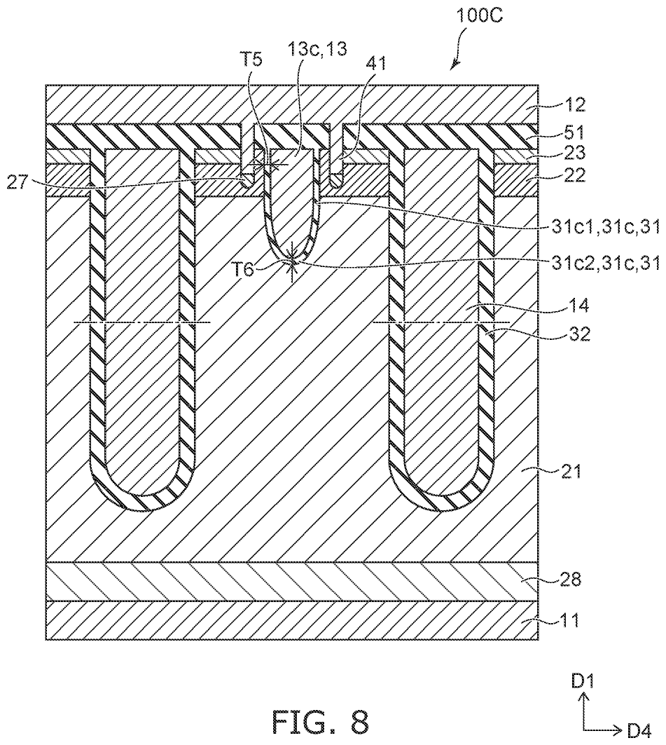

FIG. 8 is a cross-sectional view illustrating a portion of a semiconductor device according to a third modification of the first embodiment.

FIG. 8 illustrates a cross section at a position corresponding to line V-V shown in FIG. 2.

As illustrated in FIG. 8, the shape of the gate electrode 13 (the third electrode region 13c) and the shape of the gate insulating part 31 (the third insulating region 31c) of the semiconductor device 100C according to the third modification of the first embodiment are different from those of the semiconductor device 100. Otherwise, the semiconductor device 100C is the same as the semiconductor device 100.

In the semiconductor device 100C, the lower end of the third electrode region 13c is positioned lower than the lower end of the first electrode region 13a. The lower end of the third electrode region 13c is positioned lower than the lower end of the second electrode region 13b. In the semiconductor device 100C, the lower end of the first electrode region 13a is positioned at the same level as the lower end of the second electrode region 13b. The lower end of the first electrode region 13a may be positioned at a different level from the lower end of the second electrode region 13b.

In the semiconductor device 100C, the lower end of the third electrode region 13c is positioned higher than the lower end of the FP electrode 14. In the semiconductor device 100C, the lower end of the third electrode region 13c is positioned higher than the center between the upper end of the FP electrode 14 and the lower end of the FP electrode 14. In FIG. 8, the position of the center between the upper end of the FP electrode 14 and the lower end of the FP electrode 14 is illustrated by a single dot-dash line.

By positioning the lower end of the third electrode region 13c lower than the lower end of the first electrode region 13a and the lower end of the second electrode region 13b, the electric field under the third electrode region 13c can be relaxed.

By positioning the lower end of the third electrode region 13c higher than the lower end of the FP electrode 14, the gate electrode 13 can provide the same effect as the FP electrode 14, and can relax the electric field. Also, the depletion layer can be prevented from spreading more than necessary to the substrate side, and, for example, the depletion layer connecting with the substrate in avalanche breakdown (punch-through) can be prevented.

### Second Embodiment

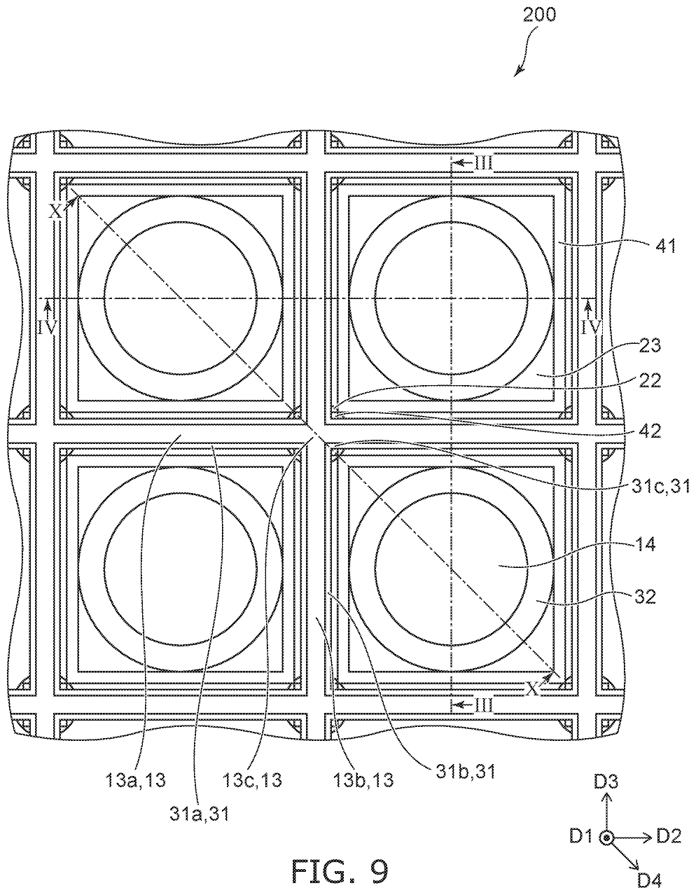

FIG. 9 is a plan view illustrating a portion of a semiconductor device according to a second embodiment.

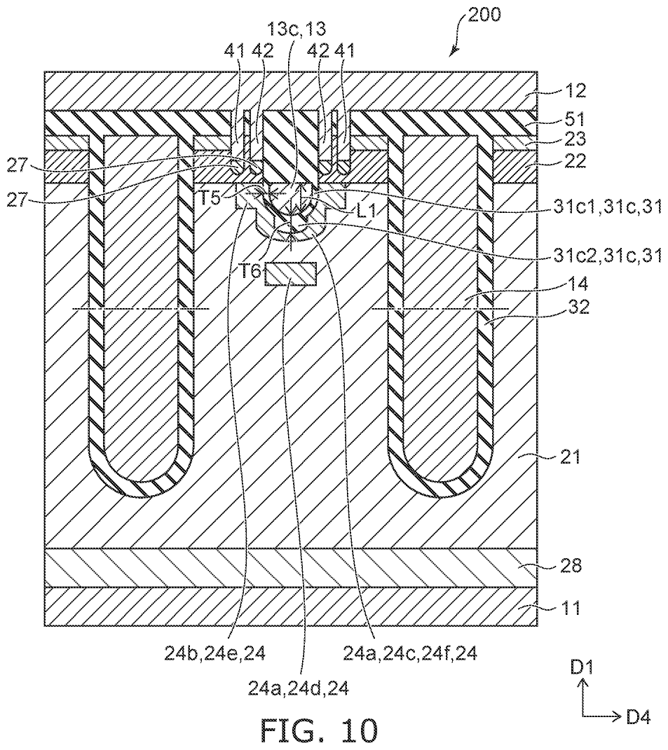

FIG. 10 is a cross-sectional view illustrating a portion of the semiconductor device according to the second embodiment.

FIG. 10 illustrates a cross section along line X-X shown in FIG. 9.

The cross section along line III-III and the cross section along line IV-IV shown in FIG. 9 are respectively the same as FIGS. 3 and 4, and are therefore omitted.

As illustrated in FIGS. 9 and 10, the semiconductor device 200 according to the second embodiment differs from the semiconductor device 100 in that the shape of the gate electrode 13 (the third electrode region 13c) and the shape of the gate insulating part 31 (the third insulating region 31c) are different, the p⁺-type semiconductor region 24 is included, and the second connection part 42 is included. Otherwise, the semiconductor device 200 is the same as the semiconductor device 100.

The semiconductor device 200 further includes the p⁺-type semiconductor region 24. The p⁺-type semiconductor region 24 is located under the sixth insulating portion 31c2. The p⁺-type semiconductor region 24 is arranged with the n⁻-type drift region 21 and the FP electrode 14 in the second direction D2, the third direction D3, and the fourth direction D4. The electric field under the third electrode region 13c can be relaxed thereby. The avalanche resistance under the third electrode region 13c can be increased. Also, the capacitance between the gate electrode 13 and the drain electrode 11 can be reduced. In the semiconductor device 200 as illustrated in FIG. 3, FIG. 4, and FIG. 10, the p⁺-type semiconductor region 24 is located under the third insulating region 31c (the sixth insulating portion 31c2) of the gate insulating part 31, but is not located under the first insulating region 31a (the second insulating portion 31a2) or under the second insulating region 31b (the fourth insulating portion 31b2). The p⁺-type semiconductor region 24 may not be included.

In the semiconductor device 200, the p⁺-type semiconductor region 24 includes a first semiconductor portion 24a and a second semiconductor portion 24b. The capacitance (Cgd) between the gate electrode 13 and the drain electrode 11 can be reduced thereby. The hole current path of the avalanche breakdown can be enlarged. Also, the holes that flow from the trench side in avalanche breakdown can be removed to the first and second connection parts 41 and 42 (the trench contacts) with low resistance. As a result, a parasitic bipolar due to the potential increase of the p-type base region 22 is not easily switched on, and the avalanche resistance improves. The first semiconductor portion 24a overlaps the gate electrode 13 (the third electrode region 13c) in the first direction D1. The second semiconductor portion 24b does not overlap the gate electrode 13 (the third electrode region 13c) in the first direction D1. The p⁺-type semiconductor region 24 may not include the first semiconductor portion 24a and the second semiconductor portion 24b.

In the semiconductor device 200, the p⁺-type semiconductor region 24 includes a third semiconductor portion 24c and a fourth semiconductor portion 24d. As a result, the p⁺-type semiconductor region 24 can be formed in multiple levels. As a result, while relaxing the electric field, the reduced area of the depletion layer of the n⁻-type drift region 21 can be compensated, and the breakdown voltage reduction due to the reduction of the depletion layer area can be suppressed. The third semiconductor portion 24c contacts the third insulating region 31c of the gate insulating part 31. The fourth semiconductor portion 24d is located under the third semiconductor portion 24c. In the semiconductor device 200, the fourth semiconductor portion 24d is separated from the third semiconductor portion 24c. The fourth semiconductor portion 24d may contact the third semiconductor portion 24c. The p⁺-type semiconductor region 24 may not include the third semiconductor portion 24c and the fourth semiconductor portion 24d.

In the semiconductor device 200, the p⁺-type semiconductor region 24 includes a fifth semiconductor portion 24e and a sixth semiconductor portion 24f. As a result, the hole current path of the hole current flowing from the gate electrode 13 side toward the first connection part 41 can be enlarged, and the resistance can be reduced. Also, the capacitance (Cgs) between the gate electrode 13 and the source electrode 12 can be reduced. The fifth semiconductor portion 24e overlaps the gate electrode 13 (the third electrode region 13c) in the fourth direction D4. The sixth semiconductor portion 24f does not overlap the gate electrode 13 (the third electrode region 13c) in the fourth direction D4. In the semiconductor device 200, the sixth semiconductor portion 24f contacts the fifth semiconductor portion 24e. The p⁺-type semiconductor region 24 may not include the fifth semiconductor portion 24e and the sixth semiconductor portion 24f.

In the semiconductor device 200, the lower end of the p⁺-type semiconductor region 24 is positioned higher than the lower end of the FP electrode 14. As a result, the depletion layer can be prevented from spreading more than necessary to the substrate side, and, for example, the depletion layer connecting with the substrate in avalanche breakdown (punch-through) can be prevented. In the semiconductor device 100, the lower end of the p⁺-type semiconductor region 24 is positioned higher than the center between the upper end of the FP electrode 14 and the lower end of the FP electrode 14. In FIG. 10, the position of the center between the upper end of the FP electrode 14 and the lower end of the FP electrode 14 is illustrated by a single dot-dash line. The lower end of the p⁺-type semiconductor region 24 may be positioned at the same level as the lower end of the FP electrode 14. The lower end of the p⁺-type semiconductor region 24 may be positioned lower than the lower end of the FP electrode 14.

In the semiconductor device 200, the lower end of the sixth insulating portion 31c2 (the third insulating region 31c) is positioned lower than the lower end of the second insulating portion 31a2 (the first insulating region 31a). The lower end of the sixth insulating portion 31c2 (the third insulating region 31c) is positioned lower than the lower end of the fourth insulating portion 31b2 (the second insulating region 31b). The electric field under the third electrode region 13c can be relaxed thereby. The lower end of the second insulating portion 31a2 (the first insulating region 31a) is positioned at the same level as the lower end of the fourth insulating portion 31b2 (the second insulating region 31b). The lower end of the second insulating portion 31a2 (the first insulating region 31a) may be positioned at a different level from the lower end of the fourth insulating portion 31b2 (the second insulating region 31b).

In the semiconductor device 200, the thickness T6 is greater than the thickness T2. The thickness T6 is greater than the thickness T4. The electric field under the third electrode region 13c can be relaxed thereby. Also, the capacitance between the gate electrode 13 and the drain electrode 11 can be reduced. The thickness T6 may be equal to the thickness T2. The thickness T6 may be less than the thickness T2. The thickness T6 may be equal to the thickness T4. The thickness T6 may be less than the thickness T4. In the semiconductor device 200, the thickness T2 is equal to the thickness T4. The thickness T2 may be different from the thickness T4.

In the semiconductor device 200, the thickness T6 is greater than the thickness T5. The capacitance (Cgd) between the gate electrode 13 and the drain electrode 11 can be reduced thereby. A reduction of the breakdown voltage can be suppressed by filling, with an oxide film or the like, the region where the distance between the FP electrodes 14 is wide and the FP electrodes 14 tend to be less effective. The thickness T6 may be equal to the thickness T5. The thickness T6 may be less than the thickness T5. In the semiconductor device 200, the thickness T2 is equal to the thickness T1. The thickness T2 may be different from the thickness T1. In the semiconductor device 200, the thickness T4 is equal to the thickness T3. The thickness T4 may be different from the thickness T3. In the semiconductor device 200, the thickness T1, the thickness T3, and the thickness T5 are equal. The thickness T1, the thickness T3, and the thickness T5 may be different from each other.

In the semiconductor device 200, the thickness T6 is greater than half of the length L1 in the first direction D1 of the third electrode region 13c. Effects are thereby obtained in which the capacitance (Cgd) between the gate electrode 13 and the drain electrode 11 is reduced, the reduction of the breakdown voltage is suppressed, etc., without reducing the cross-sectional area of the gate electrode 13 more than necessary (that is, while preventing the gate resistance from becoming too large). The thickness T6 may be less than half of the length L1. In the semiconductor device 200, the thickness T6 is less than the length L1. The thickness T6 may be equal to the length L1. The thickness T6 may be greater than the length L1.

In the semiconductor device 200, the lower end of the third electrode region 13c is positioned lower than the lower end of the first electrode region 13a. The lower end of the third electrode region 13c is positioned lower than the lower end of the second electrode region 13b. The electric field under the third electrode region 13c can be relaxed thereby. The lower end of the third electrode region 13c may be positioned at the same level as the lower end of the first electrode region 13a. The lower end of the third electrode region 13c may be positioned higher than the lower end of the first electrode region 13a. The lower end of the third electrode region 13c may be positioned at the same level as the lower end of the second electrode region 13b. The lower end of the third electrode region 13c may be positioned higher than the lower end of the second electrode region 13b. In the semiconductor device 200, the lower end of the first electrode region 13a is positioned at the same level as the lower end of the second electrode region 13b. The lower end of the first electrode region 13a may be positioned at a different level from the lower end of the second electrode region 13b.

In the semiconductor device 200, the lower end of the third electrode region 13c is positioned higher than the lower end of the FP electrode 14. As a result, the depletion layer can be prevented from spreading more than necessary to the substrate side, and, for example, the depletion layer connecting with the substrate in avalanche breakdown (punch-through) can be prevented. In the semiconductor device 200, the lower end of the third electrode region 13c is positioned higher than the center between the upper end of the FP electrode 14 and the lower end of the FP electrode 14. The lower end of the third electrode region 13c may be positioned at the same level as the lower end of the FP electrode 14. The lower end of the third electrode region 13c may be positioned lower than the lower end of the FP electrode 14.

In the semiconductor device 200, the thickness T6 is greater than the thicknesses T2 and T4; and the lower end of the third electrode region 13c is positioned lower than the lower end of the first electrode region 13a and the lower end of the second electrode region 13b. As a result, for example, compared to the semiconductor device 100C according to the third modification of the first embodiment, the increase of the capacitance can be relaxed.

In addition to the first connection part 41, the semiconductor device 200 further includes the second connection part 42. The second connection part 42 is located between the first connection part 41 and the third insulating region 31c of the gate insulating part 31 in the fourth direction D4. The p⁺-type contact region 27 is located between the second connection part 42 and the p-type base region 22 in the first direction D1. The second connection part 42 electrically connects the source electrode 12 and the p-type base region 22 (the p⁺-type contact region 27). The avalanche resistance under the third electrode region 13c can be increased thereby. Also, the capacitance between the gate electrode 13 and the drain electrode 11 can be reduced. The second connection part 42 may not be included.

In the semiconductor device 200, the second connection part 42 contacts the third insulating region 31c. The upper end of the third electrode region 13c is positioned lower than the lower end of the second connection part 42. As a result, the thickness of the portion of the gate insulating part 31 positioned between the gate electrode 13 and the second connection part 42 connected to the source electrode 12 can be not less than the thickness of the fifth insulating portion 31c1 . Short-circuits between the gate electrode 13 and the source electrode 12 can be suppressed thereby.

The second connection part 42 may be separated from the third insulating region 31c. In such a case, it is favorable for the upper end of the third electrode region 13c to be positioned higher than the lower end of the second connection part 42. As a result, the hole current path in avalanche breakdown can be short, and the rise of the potential of the p-type base region 22 due to the hole current (the parasitic bipolar being switched on) can be effectively suppressed.

In the semiconductor device 200, the upper end of the third electrode region 13c is positioned lower than the lower end of the second connection part 42; and the lower end of the third electrode region 13c is positioned lower than the lower end of the first electrode region 13a. As a result, the cross-sectional area of the gate electrode 13 becoming too small (that is, the gate resistance becoming too large) can be suppressed while suppressing short-circuits between the gate electrode 13 and the source electrode 12.

In the semiconductor device 200, the lower end of the first connection part 41 is positioned at the same level as the lower end of the second connection part 42. The lower end of the first connection part 41 may be positioned higher than the lower end of the second connection part 42 or lower than the lower end of the second connection part 42.

In the semiconductor device 200, the lower end of the first connection part 41 and the lower end of the second connection part 42 are positioned higher than the lower end of the p-type base region 22. The lower end of the second connection part 42 may be positioned lower than the lower end of the p-type base region 22. Because the p⁺-type semiconductor region 24 is included in the semiconductor device 200, the avalanche resistance can be further improved while suppressing leakage between the source electrode 12 and the drain electrode 11 when, for example, the lower end of the second connection part 42 is positioned lower than the lower end of the p-type base region 22.

In the semiconductor device 200, the second connection part 42 does not extend along the second and third directions D2 and D3. The second connection part 42 may extend along the second and third directions D2 and D3. The second connection part 42 may have an L-shape including a portion along the first electrode region 13a of the gate electrode 13 and a portion along the second electrode region 13b.

### First Manufacturing Method

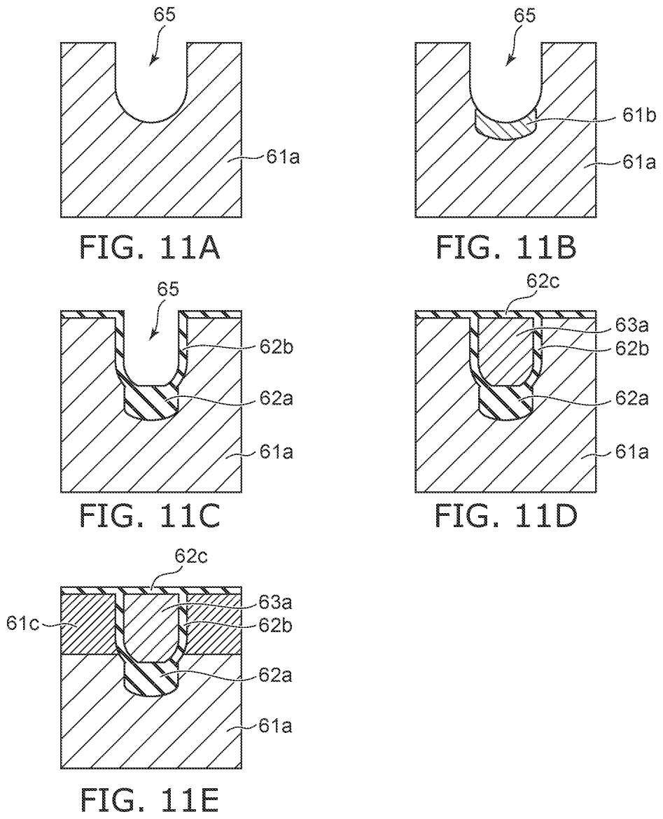

FIGS. 11A to 11E are cross-sectional views illustrating an example of a manufacturing method of the semiconductor device according to the first embodiment.

As illustrated in FIGS. 11A to 11E, the first manufacturing method includes first to fifth processes. The second process is performed after the first process. The third process is performed after the second process. The fourth process is performed after the third process. The fifth process is performed after the fourth process. FIG. 11A corresponds to the first process. FIG. 11B corresponds to the second process. FIG. 11C corresponds to the third process. FIG. 11D corresponds to the fourth process. FIG. 11E corresponds to the fifth process. The processes will now be described.

In the first process as illustrated in FIG. 11A, a trench 65 is formed in a semiconductor region 61a of the first conductivity type (e.g., the n-type). FIGS. 11A to 11E illustrate the position of the crossing point in the trench 65. The semiconductor region 61a corresponds to the n⁻-type drift region 21 described above. For example, the trench 65 is formed by etching, etc.

In the second process as illustrated in FIG. 11B, a semiconductor region 61b of the second conductivity type (e.g., the p-type) is formed under the trench 65. For example, the semiconductor region 61b is formed by implanting boron (B), BF₂, or an impurity including at least one of boron (B) or BF₂ into a semiconductor region 71a, etc.

In the third process as illustrated in FIG. 11C, the semiconductor region 61b is changed into an insulating region 62a, and an insulating region 62b is formed inside the trench 65 and on the semiconductor region 61a. The insulating region 62a and the insulating region 62b correspond to the gate insulating part 31 (the third insulating region 31c) described above. For example, the insulating region 62a and the insulating region 62b are formed by accelerated oxidation, etc.

In the fourth process as illustrated in FIG. 11D, first, a conductive region 63a is formed inside the trench 65 in which the insulating region 62b is formed. The conductive region 63a corresponds to the gate electrode 13 (the third electrode region 13c) described above. For example, the conductive region 63a is formed by filling a metal such as polysilicon or tungsten (W), etc. The polysilicon may or may not be doped with an impurity. Then, in the fourth process, an insulating region 62c is formed on the conductive region 63a. The insulating region 62c corresponds to the insulating layer 51 described above. For example, the insulating region 62c is formed by thermal oxidation, CVD (Chemical Vapor Deposition), etc. For example, the insulating region 62c may be formed by oxidizing a portion of the conductive region 63a by an annealing process when forming the conductive region 63a.

In the fifth process as illustrated in FIG. 11E, a semiconductor region 61c of the second conductivity type (e.g., the p-type) is formed in the upper portion of the semiconductor region 61a. The semiconductor region 61c corresponds to the p-type base region 22 described above. For example, the semiconductor region 61c is formed by implanting boron (B), BF₂, or an impurity including at least one of boron (B) or BF₂ into the semiconductor region 61a, etc.

According to the first manufacturing method, a semiconductor device in which the thickness T6 is greater than the thicknesses T2 and T4 can be easily manufactured. That is, according to the first manufacturing method, a semiconductor device in which the lower end of the sixth insulating portion 31c2 (the third insulating region 31c) is positioned lower than the lower end of the second insulating portion 31a2 (the first insulating region 31a) and the lower end of the fourth insulating portion 31b2 (the second insulating region 31b) can be easily manufactured. Accordingly, a semiconductor device in which the electric field can be relaxed can be easily manufactured.

### Second Manufacturing Method

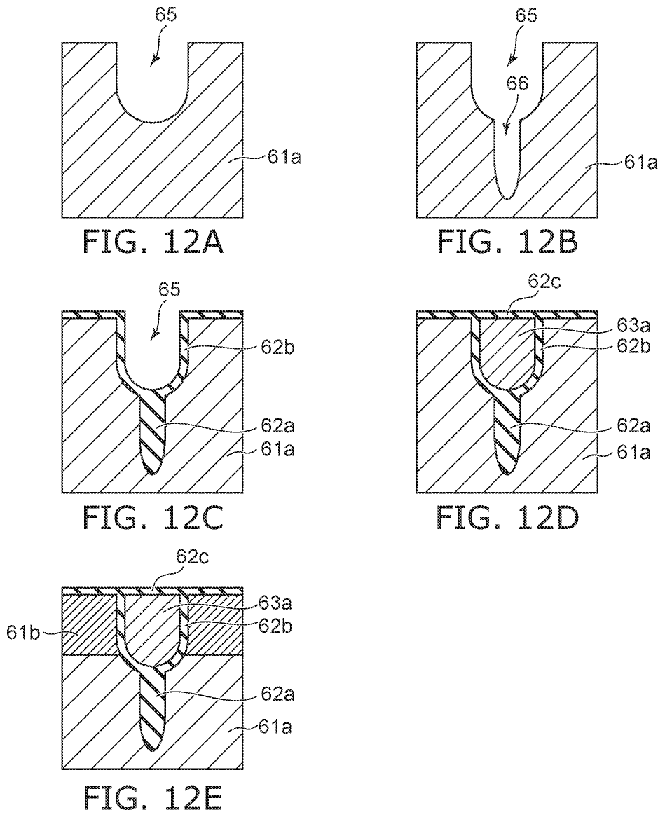

FIGS. 12A to 12E are cross-sectional views illustrating an example of a manufacturing method of a semiconductor device according to a second modification of the first embodiment.

As illustrated in FIGS. 12A to 12E, the second manufacturing method includes first to fifth processes. The second process is performed after the first process. The third process is performed after the second process. The fourth process is performed after the third process. The fifth process is performed after the fourth process. FIG. 12A corresponds to the first process. FIG. 12B corresponds to the second process. FIG. 12C corresponds to the third process. FIG. 12D corresponds to the fourth process. FIG. 12E corresponds to the fifth process. The processes will now be described.

In the first process as illustrated in FIG. 12A, the trench 65 is formed in the semiconductor region 61a of the first conductivity type (e.g., the n-type). FIGS. 12A to 12E illustrate the position of the crossing point in the trench 65. The semiconductor region 61a corresponds to the n⁻-type drift region 21 described above. For example, the trench 65 is formed by etching, etc.

In the second process as illustrated in FIG. 12B, a via 66 is formed under the crossing point of the trench 65. For example, the via 66 is formed by etching, etc.

In the third process as illustrated in FIG. 12C, the insulating region 62a is formed inside the via 66; and the insulating region 62b is formed inside the trench 65 and on the semiconductor region 61a. The insulating region 62a and the insulating region 62b correspond to the gate insulating part 31 (the third insulating region 31c) described above. For example, the insulating region 62a and the insulating region 62b are formed by etching and then by filling a CVD film, performing thermal oxidation, etc.

In the fourth process as illustrated in FIG. 12D, first, the conductive region 63a is formed inside the trench 65 in which the insulating region 62b is formed. The conductive region 63a corresponds to the gate electrode 13 (the third electrode region 13c) described above. For example, the conductive region 63a is formed by filling a metal such as polysilicon or tungsten (W), etc. The polysilicon may or may not be doped with an impurity. Then, in the fourth process, the insulating region 62c is formed on the conductive region 63a. The insulating region 62c corresponds to the insulating layer 51 described above. For example, the insulating region 62c is formed by thermal oxidation, CVD, etc. For example, the insulating region 62c may be formed by oxidizing a portion of the conductive region 63a by an annealing process when forming the conductive region 63a.

In the fifth process as illustrated in FIG. 12E, the semiconductor region 61c of the second conductivity type (e.g., the p-type) is formed in the upper portion of the semiconductor region 61a. The semiconductor region 61c corresponds to the p-type base region 22 described above. For example, the semiconductor region 61c is formed by implanting boron (B), BF₂, or an impurity including at least one of boron (B) or BF₂ into the semiconductor region 61a, etc.

According to the second manufacturing method, a semiconductor device in which the thickness T6 is greater than the thicknesses T2 and T4 can be easily manufactured. That is, according to the second manufacturing method, a semiconductor device in which the lower end of the sixth insulating portion 31c2 (the third insulating region 31c) is positioned lower than the lower end of the second insulating portion 31a2 (the first insulating region 31a) and the lower end of the fourth insulating portion 31b2 (the second insulating region 31b) can be easily manufactured. Accordingly, a semiconductor device in which the electric field can be relaxed can be easily manufactured.

### Third Manufacturing Method

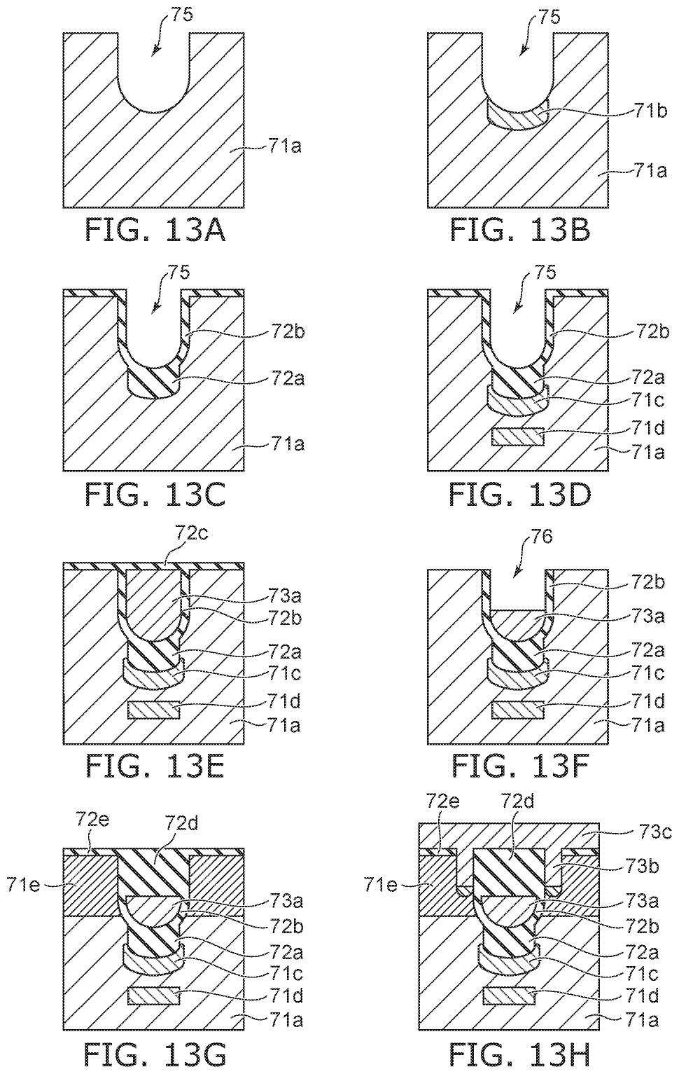

FIGS. 13A to 13H are cross-sectional views illustrating an example of a manufacturing method of the semiconductor device according to the second embodiment.

As illustrated in FIGS. 13A to 13H, the third manufacturing method includes first to eighth processes. The second process is performed after the first process. The third process is performed after the second process. The fourth process is performed after the third process. The fifth process is performed after the fourth process. The sixth process is performed after the fifth process. The seventh process is performed after the sixth process. The eighth process is performed after the seventh process. FIG. 13A corresponds to the first process. FIG. 13B corresponds to the second process. FIG. 13C corresponds to the third process. FIG. 13D corresponds to the fourth process. FIG. 13E corresponds to the fifth process. FIG. 13F corresponds to the sixth process. FIG. 13G corresponds to the seventh process. FIG. 13H corresponds to the eighth process. The processes will now be described.

In the first process as illustrated in FIG. 12A, a trench 75 is formed in the semiconductor region 71a of the first conductivity type (e.g., the n-type). FIGS. 13A to 13H illustrate the position of the crossing point in the trench 75. The semiconductor region 71a corresponds to the n⁻-type drift region 21 described above. For example, the trench 75 is formed by etching, etc.

In the second process as illustrated in FIG. 13B, a semiconductor region 71b of the second conductivity type (e.g., the p-type) is formed under the trench 75. For example, the semiconductor region 71b is formed by implanting boron (B), BF₂, or an impurity including at least one of boron (B) or BF₂ into the semiconductor region 71a, etc.

In the third process as illustrated in FIG. 13C, the semiconductor region 71b is changed into an insulating region 72a; and an insulating region 72b is formed inside the trench 75 and on the semiconductor region 71a. The insulating region 72a and the insulating region 72b correspond to the gate insulating part 31 (the third insulating region 31c) described above. For example, the insulating region 72a and the insulating region 72b are formed by accelerated oxidation, etc.

In the fourth process as illustrated in FIG. 13D, a semiconductor region 71c and a semiconductor region 71d of the second conductivity type (e.g., the p-type) are formed under the insulating region 72a. The semiconductor region 71c and the semiconductor region 71d correspond to the p⁺-type semiconductor region 24 described above. For example, the semiconductor region 71c and the semiconductor region 71d are formed by implanting boron (B), BF₂, or an impurity including at least one of boron (B) or BF₂ into the semiconductor region 71a, etc.

In the fifth process as illustrated in FIG. 13E, first, a conductive region 73a is formed inside the trench 75 in which the insulating region 72b is formed. The conductive region 73a corresponds to the gate electrode 13 (the third electrode region 13c) described above. For example, the conductive region 73a is formed by filling a metal such as polysilicon or tungsten (W), etc. The polysilicon may or may not be doped with an impurity. An insulating region 72c is formed on the conductive region 73a by oxidizing a portion of the conductive region 73a by an annealing process when forming the conductive region 73a.

In the sixth process as illustrated in FIG. 13F, first, the insulating region 72b formed on the semiconductor region 71a and the insulating region 72c formed on the conductive region 73a are removed. For example, the insulating region 72b and the insulating region 72c are removed by CMP (Chemical Mechanical Polishing), etching, etc. The etching is, for example, CDE (Chemical Dry Etching). Then, in the sixth process, a via 76 is formed by removing a portion (the upper portion) of the conductive region 73a. For example, the via 76 is formed by etching, etc.

In the seventh process as illustrated in FIG. 13G, first, an insulating region 72d is formed inside the via 76; and an insulating region 72e is formed on the insulating region 72d and the semiconductor region 71a. The insulating region 72d corresponds to the gate insulating part 31 (the third insulating region 31c) described above. The insulating region 72e corresponds to the insulating layer 51 described above. For example, the insulating region 72d and the insulating region 72e are formed by thermal oxidation, CVD, etc. Then, in the seventh process, a semiconductor region 71e of the second conductivity type (e.g., the p-type) is formed in the upper portion of the semiconductor region 71a. The semiconductor region 71e corresponds to the p-type base region 22 described above. For example, the semiconductor region 71e is formed by implanting boron (B), BF₂, or an impurity including at least one of boron (B) or BF₂ into the semiconductor region 71a, etc.

In the eighth process as illustrated in FIG. 13H, first, a conductive region 73b is formed at the two sides of the portion of the insulating region 72d positioned on the conductive region 73a. The conductive region 73b corresponds to the second connection part 42 described above. For example, the conductive region 73b is formed by filling tungsten (W) with CVD, sputtering a barrier metal, etc. Then, in the eighth process, a conductive region 73c is formed on the insulating region 72e and the conductive region 73b. The conductive region 73c corresponds to the source electrode 12 described above. For example, the conductive region 73c is formed by depositing a metal such as aluminum (Al), etc.

According to the third manufacturing method, a semiconductor device can be easily manufactured in which the p⁺-type semiconductor region 24 is located under the third electrode region 13c of the gate electrode 13, the lower end of the third insulating region 31c (the sixth insulating portion 31c2) of the gate insulating part 31 is positioned lower than the lower end of the first insulating region 31a (the second insulating portion 31a2) and the lower end of the second insulating region 31b (the fourth insulating portion 31b2), and the second connection part 42 is located at the side of the third insulating region 31c of the gate insulating part 31. Accordingly, a semiconductor device in which the electric field can be relaxed can be easily manufactured.

Embodiments may include the following configurations.

### Configuration 1

A semiconductor device, comprising:
a first electrode;
a first semiconductor region located on the first electrode, the first semiconductor region being of a first conductivity type;
a second semiconductor region located on the first semiconductor region, the second semiconductor region being of a second conductivity type;
a third semiconductor region located on the second semiconductor region, the third semiconductor region being of the first conductivity type;
a second electrode located on the third semiconductor region, the second electrode being electrically connected with the third semiconductor region;
a third electrode including
   a first electrode region extending along a second direction perpendicular to a first direction, the first electrode region being arranged with the second semiconductor region in a third direction, the first direction being from the first electrode toward the second electrode, the third direction being perpendicular to the first direction and crossing the second direction,
   a second electrode region extending along the third direction, the second electrode region being arranged with the second semiconductor region in the second direction, and
   a third electrode region connecting the first electrode region and the second electrode region;
a first insulating part including
   a first insulating region including
      a first insulating portion located between the second semiconductor region and the first electrode region in the third direction, and
      a second insulating portion located between the first semiconductor region and the first electrode region in the first direction,
   a second insulating region including
      a third insulating portion located between the second semiconductor region and the second electrode region in the second direction, and
      a fourth insulating portion located between the first semiconductor region and the second electrode region in the first direction, and
   a third insulating region connecting the first insulating region and the second insulating region, the third insulating region including
      a fifth insulating portion located between the second semiconductor region and the second electrode region in a fourth direction, the fourth direction being perpendicular to the first direction and crossing the second and third directions, and
      a sixth insulating portion located between the first semiconductor region and the third electrode region in the first direction;
a fourth electrode arranged with the first semiconductor region and the third electrode in the second and third directions; and
a second insulating part located between the fourth electrode and the first semiconductor region and between the fourth electrode and the third electrode in the second and third directions,
a lower end of the sixth insulating portion being positioned lower than a lower end of the second insulating portion and a lower end of the fourth insulating portion.

### Configuration 2

The device according to configuration 1, wherein
a thickness in the first direction of the sixth insulating portion is greater than a thickness in the first direction of the second insulating portion and a thickness in the first direction of the fourth insulating portion.

### Configuration 3

The device according to configuration 1 or 2, wherein
the thickness in the first direction of the sixth insulating portion is greater than a thickness in the fourth direction of the fifth insulating portion.

### Configuration 4

The device according to any one of configurations 1 to 3, wherein
the thickness in the first direction of the sixth insulating portion is greater than half of a length in the first direction of the third electrode region.

### Configuration 5

The device according to any one of configurations 1 to 4, wherein
a lower end of the third electrode region is positioned lower than a lower end of the first electrode region and a lower end of the second electrode region.

### Configuration 6

The device according to any one of configurations 1 to 5, wherein
the lower end of the third electrode region is positioned higher than a lower end of the fourth electrode.

### Configuration 7

The device according to any one of configurations 1 to 6, further comprising:
a fourth semiconductor region located under the sixth insulating portion,
the fourth semiconductor region being of the second conductivity type.

### Configuration 8

The device according to any one of configurations 1 to 7, further comprising:
a first connection part located between the third insulating region and the second insulating part in the second and third directions, the first connection part electrically connecting the second electrode and the second semiconductor region; and
a second connection part located between the third insulating region and the first connection part in the fourth direction, the second connection part electrically connecting the second electrode and the second semiconductor region.

### Configuration 9

The device according to any one of configurations 1 to 8, wherein
a width in the fourth direction of the sixth insulating portion is less than a width in the fourth direction of the third electrode region.

### Configuration 10

The device according to any one of configurations 1 to 8, wherein
a width in the fourth direction of the sixth insulating portion is equal to a width in the fourth direction of the third electrode region.

### Configuration 11

The device according to any one of configurations 1 to 10, wherein

a lower end of the second insulating portion, a lower end of the fourth insulating portion, and a lower end of the sixth insulating portion each are positioned higher than a center between an upper end of the fourth electrode and a lower end of the fourth electrode.

Thus, according to embodiments, a semiconductor device can be provided in which the electric field can be relaxed.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions. Additionally, the embodiments described above can be combined mutually.

What is claimed is:

1. A semiconductor device, comprising:
a first electrode;
a first semiconductor region located on the first electrode, the first semiconductor region being of a first conductivity type;
a second semiconductor region located on the first semiconductor region, the second semiconductor region being of a second conductivity type;
a third semiconductor region located on the second semiconductor region, the third semiconductor region being of the first conductivity type;
a second electrode located on the third semiconductor region, the second electrode being electrically connected with the third semiconductor region;
a third electrode including
a first electrode region extending along a second direction perpendicular to a first direction, the first electrode region being arranged with the second semiconductor region in a third direction, the first direction being from the first electrode toward the second electrode, the third direction being perpendicular to the first direction and crossing the second direction,
a second electrode region extending along the third direction, the second electrode region being arranged with the second semiconductor region in the second direction, and
a third electrode region connecting the first electrode region and the second electrode region;
a first insulating part including
a first insulating region including
a first insulating portion located between the second semiconductor region and the first electrode region in the third direction, and
a second insulating portion located between the first semiconductor region and the first electrode region in the first direction,
a second insulating region including
a third insulating portion located between the second semiconductor region and the second electrode region in the second direction, and
a fourth insulating portion located between the first semiconductor region and the second electrode region in the first direction, and
a third insulating region connecting the first insulating region and the second insulating region, the third insulating region including
a fifth insulating portion located between the second semiconductor region and the second electrode region in a fourth direction, the fourth direction being perpendicular to the first direction and crossing the second and third directions, and
a sixth insulating portion located between the first semiconductor region and the third electrode region in the first direction;
a fourth electrode arranged with the first semiconductor region and the third electrode in the second and third directions; and
a second insulating part located between the fourth electrode and the first semiconductor region and between the fourth electrode and the third electrode in the second and third directions,
a lower end of the sixth insulating portion being positioned lower than a lower end of the second insulating portion and a lower end of the fourth insulating portion.

2. The device according to claim 1, wherein
a thickness in the first direction of the sixth insulating portion is greater than a thickness in the first direction of the second insulating portion and a thickness in the first direction of the fourth insulating portion.

3. The device according to claim 2, wherein
the thickness in the first direction of the sixth insulating portion is greater than a thickness in the fourth direction of the fifth insulating portion.

4. The device according to claim 2, wherein
the thickness in the first direction of the sixth insulating portion is greater than half of a length in the first direction of the third electrode region.

5. The device according to claim 1, wherein
a lower end of the third electrode region is positioned lower than a lower end of the first electrode region and a lower end of the second electrode region.

6. The device according to claim 5, wherein
the lower end of the third electrode region is positioned higher than a lower end of the fourth electrode.

7. The device according to claim 1, further comprising:
a fourth semiconductor region located under the sixth insulating portion,
the fourth semiconductor region being of the second conductivity type.

8. The device according to claim 1, further comprising:
a first connection part located between the third insulating region and the second insulating part in the second and third directions, the first connection part electrically connecting the second electrode and the second semiconductor region; and
a second connection part located between the third insulating region and the first connection part in the fourth direction, the second connection part electrically connecting the second electrode and the second semiconductor region.

9. The device according to claim 1, wherein
a width in the fourth direction of the sixth insulating portion is less than a width in the fourth direction of the third electrode region.

10. The device according to claim 1, wherein
a width in the fourth direction of the sixth insulating portion is equal to a width in the fourth direction of the third electrode region.

11. The device according to claim 1, wherein
a lower end of the second insulating portion, a lower end of the fourth insulating portion, and a lower end of the sixth insulating portion each are positioned higher than a center between an upper end of the fourth electrode and a lower end of the fourth electrode.
